(19) United States
(12) Patent Application Publication
(10) Pub. No.: US 2026/0223319 A1
(43) Pub. Date: Jul. 30, 2026

(54) Open Bath and Modular Immersion Cooling System for High-Powered Compute Nodes Using Dielectric Fluid

(71) Applicant: Gamma Technologies LLC, ALBUQUERQUE, NM (US)

(72) Inventor: Richard Margerison, Del Valle, TX (US)

(21) Appl. No.: 19/039,879

(22) Filed: Jan. 29, 2025

(51) Int. Cl. H05K 7/20

(52) U.S. Cl. CPC H05K 7/20236; H05K 7/20245; H05K 7/20272; H05K 7/20281

(57) ABSTRACT

The present invention provides a single-phase immersion cooling system for high-powered electronic devices, designed to improve thermal management using a dielectric cooling fluid that remains in its liquid phase throughout operation. The system includes a fully integrated Coolant Distribution Unit (CDU) that delivers the cooling fluid uniformly across the tank floor, ensuring equalized laminar flow and eliminating thermal inconsistencies. An indirect spiraling fluid injection system creates a mixing effect to distribute the cooling fluid evenly while facilitating upward BTU transfer. A modular support structure positions electronic devices above the fluid flow and incorporates a self-sealing design to ensure that 100% of the cooling fluid passes through the devices, maximizing thermal efficiency. The invention also features a modular passive basin for regulating fluid flow, preventing overflow, and providing scalable multi-tank configurations. By utilizing a gravity-based fluid return mechanism, the system lowers the need for powerful expensive pumps or complex plumbing.

### BACKGROUND OF THE INVENTION

### Field of Invention

The present invention pertains to the field of immersion cooling technologies for electronic devices. More particularly, it relates to systems and methods for the thermal management of high-performance electronic devices, such as servers, cryptocurrency mining units, and other compute-intensive hardware, through the use of open bath immersion cooling systems. The invention utilizes a thermally conductive yet electrically non-conductive dielectric fluid to provide efficient cooling for electronic devices submerged in one or more tanks. The system is designed to optimize cooling performance through features that address challenges in fluid distribution, flow control, and modularity in deployment, making it especially suited for applications in data centers, hyperscale computing environments, enterprise-level computing, and cryptocurrency mining operations.

The invention is distinguished by its focus on integrating the most critical aspects of immersion cooling—fluid management, deployment efficiency, and modular design—while minimizing installation complexity and operational costs. This includes innovative features such as fully integrated single-or multi-tank fluid distribution units, self-sealing modular designs for compute node housings, and systems for balanced laminar fluid flow and drain-back protection. The invention further enables scalability and adaptability for diverse infrastructure configurations, offering significant advancements over prior art in the field.

### BRIEF SUMMARY OF THE INVENTION

The present invention relates to an innovative open bath immersion cooling system for electronic devices, particularly high-powered compute nodes, designed to optimize heat dissipation and improve system efficiency using dielectric fluids. The invention integrates multiple novel features, including a fully modular design, gravity-based fluid return mechanisms, an indirect spiraling fluid injection system, and a device-neutral support system. Together, these features eliminate the need for traditional plumbing, reduce deployment time and material costs, and simplify the installation and operation of immersion cooling systems.

This invention provides a single or multi-tank configuration with a fully integrated coolant distribution unit (CDU) that ensures uniform fluid distribution across the bottom of the tank, creating equalized laminar flow. Each compute node is sealed in a manner that ensures 100% of the cooling fluid passes through the electronic devices, eliminating fluid bypass and optimizing thermal transfer. Additionally, the system incorporates overflow protection mechanisms and modular passive basins that prevent fluid spills under emergency conditions.

By addressing the limitations of existing systems, such as the complexity and cost of deployment, as well as the inefficiency of fluid distribution methods, this invention represents a significant advancement in immersion cooling technology. The solution is particularly suited for data centers, cryptocurrency mining operations, hyperscale computing, and similar environments, enabling faster, turnkey deployment while minimizing operational expenses (OPEX) while improving Power Usage Effectiveness (PUE).

### BRIEF DESCRIPTION OF THE FIGURES

FIG. 1: A fully integrated single or multi-tank Coolant Distribution Unit (CDU) ensures uniform coolant delivery and fluid mixing for optimal heat dissipation across the tank floor.

FIG. 2: The indirect spiraling fluid injection system creates uniform fluid distribution by leveraging strategically placed exit ports to achieve a mixing and spiraling effect.

FIG. 3: The device-neutral support system positions compute nodes above fluid injection points, ensuring efficient cooling for multiple device types without fluid bypass.

FIG. 4: A self-sealing support system ensures compute nodes are fully enclosed within the cooling system, preventing fluid bypass and maximizing thermal efficiency.

FIG. 5: A fully integrated modular passive basin controls fluid flow and prevents overflow during standard and emergency conditions.

FIG. 6A: The system's fluid level under typical conditions, with adequate overflow capacity to handle normal operations.

FIG. 6B: The system's fluid level under emergency conditions, demonstrating its ability to safely handle unexpected surges or failures without fluid spills.

### DETAILED DESCRIPTION

The present invention relates to a single-phase immersion cooling system designed to efficiently manage the thermal demands of high-powered compute nodes. The invention is particularly suitable for applications such as data centers, cryptocurrency mining, high-performance computing (HPC), and enterprise computing environments, where reliable and efficient cooling is essential. This system leverages dielectric cooling fluids that remain in their liquid phase throughout operation to maintain consistent and reliable cooling performance without undergoing any phase changes. The system incorporates innovative design features that simplify deployment, enhance operational efficiency, and reduce overall costs compared to conventional single-phase cooling systems.

### Fully Integrated Single or Multi-Tank Coolant Distribution Unit (CDU)

The invention employs a fully integrated Coolant Distribution Unit (CDU) to deliver cooling fluid uniformly across the bottom of a single or multi-tank system. The CDU eliminates the need for external piping or complex plumbing systems by integrating all fluid delivery and return mechanisms directly into the tank structure.

Cooling fluid enters the system through a primary conduit, represented as a grey rectangular tube, which serves as the central distribution channel. The fluid is then directed into a network of yellow tubes, which traverse the length of the tank. These yellow tubes distribute the cooling fluid into red tubes, strategically modified with exit ports to enable precise fluid discharge. As fluid exits the red tubes, it is delivered uniformly to the bottom of the tank in a controlled manner, ensuring equalized laminar flow. This uniform flow eliminates thermal “dead spots,” which are areas where inadequate cooling can result in device overheating.

In multi-tank configurations, the CDU enables fluid sharing between tanks, ensuring consistent performance across all tanks in the system. This modular approach allows operators to expand the cooling system as needed without disrupting the existing setup. The integrated CDU design not only simplifies the cooling system's infrastructure but also reduces deployment time and material costs.

### Indirect Spiraling Fluid Injection System

The indirect spiraling fluid injection system is a critical innovation designed to optimize fluid distribution within the tank. As cooling fluid exits the red tubes of the CDU, it is introduced into the tank through strategically positioned exit ports. These exit ports are angled and configured to generate a spiraling flow pattern.

The spiraling flow pushes the cooler fluid to all areas of the tank floor, ensuring comprehensive coverage and effective heat absorption. This mixing effect prevents thermal gradients and ensures that the cooling fluid maintains a consistent temperature profile throughout the tank. As the velocity of the fluid slows near the bottom of the tank, the fluid naturally begins to flow upward, passing over the immersed electronic devices and absorbing the heat generated by them.

This design eliminates the need for additional mechanical mixing components, relying instead on the natural properties of the spiraling fluid flow to achieve even distribution. By ensuring complete and consistent coverage of the tank floor, the system maximizes thermal transfer efficiency and maintains optimal cooling performance for all devices within the tank.

### Device-Neutral Support System

The invention includes a device-neutral support system that positions electronic devices above the fluid injection points to ensure maximum exposure to the cooling fluid. This modular support structure is adaptable to various device types, including ASIC miners, GPUs, servers, and other compute nodes, without requiring customized mounting hardware.

The red tubes of the CDU serve a dual purpose: they act as fluid conduits and provide structural support for the devices. Compute nodes are mounted directly above the red tubes, ensuring that 100% of the cooling fluid flows through the devices rather than bypassing them. This configuration eliminates wasted fluid flow and ensures that each device receives the necessary cooling to maintain its operational temperature.

The support system accommodates devices of varying sizes and configurations by using adjustable mounting points. This adaptability allows users to mix and match different types of devices within the same tank, making the system suitable for a wide range of applications. By ensuring efficient fluid-to-device contact and eliminating fluid bypass, the support system optimizes the overall thermal performance of the system.

### Self-Sealing Design on the Support System

The support system also incorporates a self-sealing design to enhance thermal efficiency and prevent fluid bypass. Each compute node is sealed securely within the system using a dual-triangle configuration that creates a snug fit on both sides of the device. This ensures that all cooling fluid passes directly through the compute devices rather than flowing around them.

The self-sealing design accommodates a variety of compute node sizes, ensuring compatibility with devices of different widths and form factors. By eliminating gaps between the devices and the sealing structure, the system ensures that no pumped cooling fluid is wasted and that maximum heat transfer occurs. Additionally, this design improves the structural stability of the setup, allowing for high-density device deployments without compromising performance or reliability.

### Fully Integrated Modular Passive Basin

The modular passive basin is a central feature of the invention, designed to regulate fluid flow within the tank and provide overflow protection. Positioned at the center of the tank, the basin divides the tank into discrete zones and reduces the length of the fluid return path by 50%. This shorter path ensures efficient recirculation of the cooling fluid and prevents issues such as stagnation or uneven fluid collections.

During normal operation, the basin maintains a stable fluid level, providing sufficient capacity to handle variations in coolant volume. The basin also features built-in overflow protection mechanisms, which allow it to absorb surges or drain back in fluid volume caused by operational changes or unexpected events. This ensures that the system remains safe and reliable under all conditions without overflow.

The modular design of the basin makes it adaptable to both single-tank and multi-tank configurations. This scalability allows users to expand the system as needed without requiring extensive reconfiguration or additional infrastructure.

### System Drain-Back Protection for Single and Multi-Tank Configurations

The system includes a gravity-based drain-back protection mechanism that ensures consistent fluid levels and prevents overflow in both single-tank and multi-tank configurations. Excess or unused fluid is returned to a centralized collection point via gravity, eliminating the need for pumps or other mechanical components.

This feature is particularly beneficial in multi-tank setups, where fluid sharing between tanks must be carefully managed to prevent imbalances. The drain-back system ensures that all tanks maintain stable fluid levels, even under varying operational conditions. This reduces the risk of equipment damage and minimizes maintenance requirements.

### Modular and Turnkey Design

A defining feature of the invention is its modular and turnkey design, which simplifies deployment and minimizes disruption to existing infrastructure. The system is designed for rapid installation without the need for certified plumbing, special equipment and/or extensive training. All critical components are integrated directly into the tank structure, allowing the system to be deployed and operational in a fraction of the time required for conventional cooling solutions.

This modularity also extends to the compute nodes, which can be added, removed, or reconfigured without affecting the overall system. This flexibility makes the system suitable for a wide range of applications, including data centers, enterprise computing, and cryptocurrency mining.

### Applications and Advantages

The invention is particularly well-suited for use in data centers, cryptocurrency mining operations, high-performance computing environments, and hyperscale computing systems. It provides significant advantages over traditional air-cooled and liquid-cooled systems by reducing operational costs, improving thermal performance, and simplifying deployment.

By leveraging a single-phase immersion cooling approach, the system eliminates the complexity and inefficiency (such as vapor loss) associated with two-phase immersion cooling systems (2PIC). The use of dielectric fluids ensures safe and reliable operation, while the modular design enables scalability and adaptability for future enhancements.

### Detailed Description of Figures

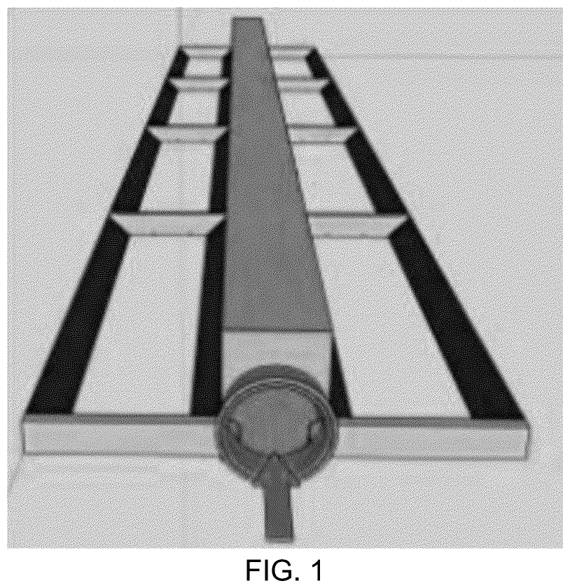

FIG. 1: Fully Integrated Single or Multi-Tank Coolant Distribution Unit (CDU)—Illustrates the design and operation of a fully integrated Coolant Distribution Unit (CDU), which provides uniform parallel coolant delivery across the bottom of a single or multi-tank immersion cooling system. Cool dielectric fluid enters the system through a grey rectangular conduit, which serves as a central distribution channel. From this conduit, the fluid is directed into yellow tubes, which traverse the system and distribute the coolant evenly. The yellow tubes sit lower than the red tubes to ensure no dead spots are created by the yellow tubes which have strategically positioned exit ports to address potential hot spots. The yellow tubes connect to red tubes, which are modified with strategically positioned exit ports to facilitate controlled fluid discharge. The fluid exits the assembly at specific angles and locations, creating a mixing effect at the bottom of the tank. This mixing ensures cooler fluid is evenly distributed across the tank floor, eliminating thermal dead spots and maximizing heat transfer efficiency. In multi-tank configurations, the CDU enables fluid sharing between tanks through integrated connections, ensuring consistent cooling performance throughout the system.

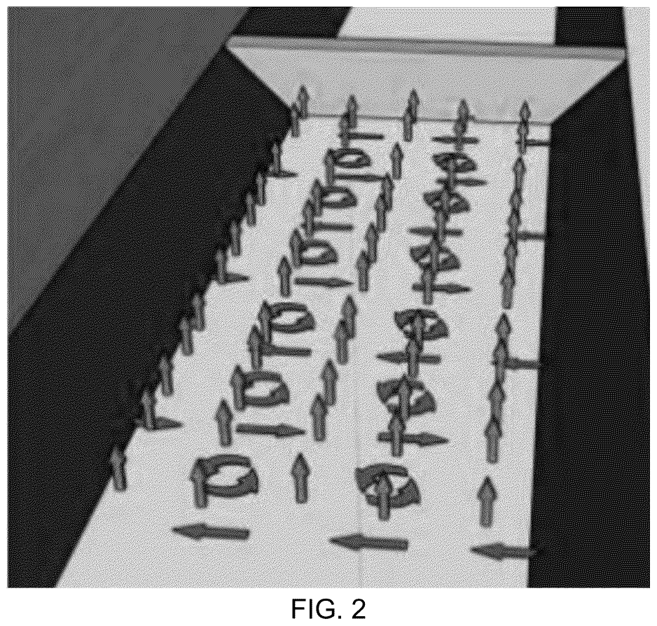

FIG. 2: Indirect Spiraling Fluid Injection System—Depicts the indirect spiraling fluid injection system, a key component of the cooling system that enhances fluid distribution and heat transfer. As coolant exits the red tubes, the placement and orientation of the exit ports naturally induce a spiraling flow pattern. This spiraling action ensures that the fluid is directed to all areas of the tank floor with minimal velocity loss. The upward motion of the fluid begins as its velocity decreases near the tank floor, ensuring consistent and complete coverage of all immersed compute nodes. By leveraging this natural mixing and spiraling effect, the system eliminates the need for additional mechanical components or flow plates to achieve uniform fluid distribution, thereby simplifying the design and reducing operational costs. This mechanism ensures that the cooling fluid effectively absorbs heat from all devices, regardless of their position within the tank.

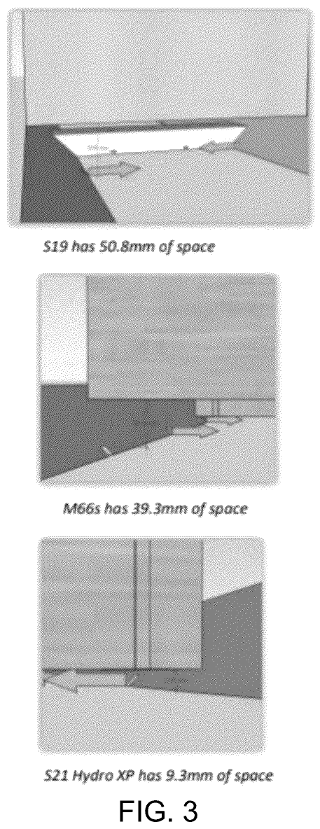

FIG. 3: Device-Neutral Support System—Showcases the device-neutral support system, a modular structure designed to accommodate a wide range of electronic devices, including servers, cryptocurrency miners, and GPUs. The red tubes, which form part of the coolant distribution system, also function as mounting points for compute devices. This dual-purpose design ensures that all devices are positioned above the fluid exit ports, automatically sealing the compute device to the red tubes allowing them to receive 100% of the cooling fluid flow without any bypass. The support system is static but the slope of the triangle shape enables varying width devices not only to seal, but can grant height-adjustable characteristics to accommodate devices of these varying sizes, ensuring compatibility with multiple hardware configurations. The system's ability to support multiple device types provides flexibility for a wide range of applications, such as data centers and cryptocurrency mining. By preventing fluid wastage and ensuring optimal fluid-to-device contact, the support system maximizes thermal transfer efficiency and minimizes energy consumption.

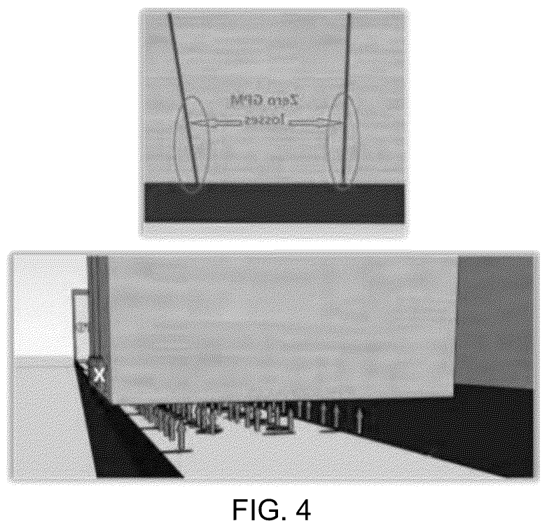

FIG. 4: Self-Sealing Design on the Support System—Illustrates the self-sealing design of the support system, which ensures that compute nodes are fully enclosed and that all cooling fluid flows directly through the devices. The support system features a dual-triangle configuration, enabling a snug-fitting seal on either side of each compute node. This design accommodates nodes of varying sizes and ensures that the nodes can be positioned tightly against one another without gaps, once again eliminating the risk of fluid bypass. By forcing the cooling fluid through the compute devices rather than allowing it to flow around them, this sealing mechanism maximizes the efficiency of the cooling process and reduces the pumping requirements of the system. Additionally, the self-sealing design reduces the risk of leaks and ensures consistent performance under various operating conditions. The tight fit between the nodes and the support system also enhances the structural stability of the arrangement, allowing for reliable operation in high-density deployments.

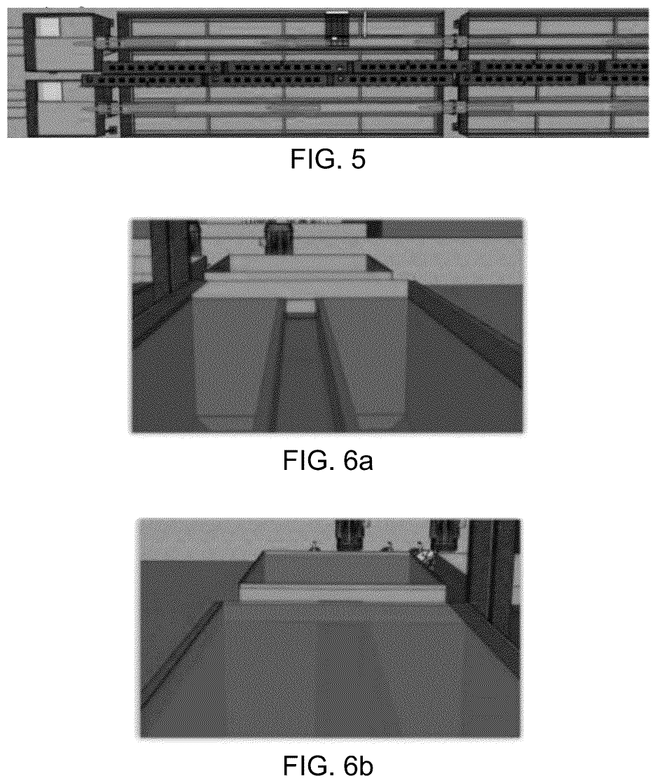

FIG. 5: Fully Integrated Modular Passive Basin—Illustrates the fully integrated modular passive basin, a critical component designed to regulate fluid flow and provide overflow protection. The basin is positioned at the end of a tank or between multiple tanks serving to manage coolant levels during normal and emergency operations. By dividing the tank into discrete zones, the modular flexible basin can reduce the fluid path by 50%, ensuring efficient recirculation and minimizing the risk of overflow. During normal operation, the basin maintains a stable fluid level, while its modular design allows it to adapt to single-tank or multi-tank configurations. The basin also provides an additional layer of safety by absorbing surges in fluid volume caused by rapid temperature changes or other unforeseen conditions. Its design is optimized to ensure that fluid returns to the cooling tower or centralized collection point without spillage, protecting both the equipment and the surrounding environment.

FIGS. 6A and 6B: Fluid Levels Under Normal and Emergency Conditions

FIG. 6A: Typical Fluid Level—Represents the system's fluid level under normal operating conditions. The coolant level is maintained at a height sufficient to ensure complete immersion of the compute nodes while providing hundreds of gallons of overflow capacity. This capacity allows the system to handle fluctuations in fluid volume without risk of spillage. The basin's passive design ensures efficient fluid recirculation and even distribution throughout the tank during regular operation.

FIG. 6B: Emergency Fluid Level—Depicts the system's fluid level during emergency conditions, such as rapid changes in temperature or power failures. The modular passive basin provides sufficient overflow capacity to absorb any sudden increases in fluid volume, preventing spills and ensuring the integrity of the system. By directing excess fluid into designated overflow zones, the system maintains stable operation even under challenging conditions and curtailments. This feature is critical for protecting sensitive electronic devices and minimizing downtime in mission-critical applications.

What is claimed is:

1. An immersion cooling system for electronic devices, the system comprising:
a tank configured to contain a dielectric cooling fluid in liquid form, the tank including:
a. a front portion having an opening for receiving the cooling fluid,
b. a rear portion in fluid communication with said front portion,
c. one or more fluid conduits configured to deliver the cooling fluid to the bottom of the tank, ensuring uniform distribution of the cooling fluid in a laminar flow across the tank floor, and
d. A gravity-based fluid return mechanism for recirculating the cooling fluid;
one or more electronic devices immersed in the cooling fluid; and
a modular support structure within the tank for positioning said electronic devices,
wherein said support structure is configured to ensure that 100% of the cooling fluid flows through said electronic devices.

2. The system of claim 1, wherein the tank includes a coolant distribution unit (CDU) comprising:
a. An integrated central conduit for receiving the cooling fluid,
b. a network of integrated primary and secondary conduits configured to deliver the cooling fluid to the bottom of the tank, and
c. exit ports in the secondary conduits configured to generate a mixing effect that evenly distributes the cooling fluid across the tank floor.

3. The system of claim 1, wherein the tank further comprises a modular passive basin positioned at the center of the tank, the modular passive basin being configured to:
a. reduce the length of the fluid path within the tank,
b. regulate the flow of cooling fluid between zones of the tank, and
c. provide overflow protection during both normal and emergency operations.

4. The system of claim 1, wherein the fluid conduits include an indirect spiraling fluid injection system, said injection system being configured to:
a. direct the cooling fluid through strategically positioned exit ports,
b. create a spiraling flow that distributes the cooling fluid evenly across the tank floor, and
c. ensure upward movement of the cooling fluid for efficient heat transfer to immersed electronic devices.

5. The system of claim 1, wherein the modular support structure includes:
a. a mounting system for securing electronic devices above the fluid conduits,
b. a self-sealing mechanism for ensuring all cooling fluid flows through the electronic devices without bypass, and
c. Flexible mounting points to accommodate electronic devices of varying sizes and configurations.

6. The system of claim 5, wherein the self-sealing mechanism includes a dual-triangle configuration that creates a snug fit for electronic devices, ensuring no fluid bypass occurs.

7. The system of claim 1, further comprising a drain-back protection mechanism configured to:
a. return unused or excess cooling fluid to a centralized collection point via gravity, and
b. maintain consistent fluid levels in both single-tank and multi-tank configurations.

8. The system of claim 1, wherein the tank is scalable to a multi-tank configuration, and wherein the tanks are connected to share cooling fluid through an integrated fluid distribution system.

9. The system of claim 1, wherein the cooling fluid is a single-phase dielectric liquid that remains in liquid form during operation and is thermally conductive yet electrically non-conductive.

10. The system of claim 1, wherein the system is configured for use in environments requiring efficient thermal management, including data centers, cryptocurrency mining operations, and high-performance computing systems.

11. The system of claim 1, wherein the cooling fluid is returned to the tank solely via gravity, without the need for mechanical pumps.

12. The system of claim 1, wherein the modular design enables turnkey deployment, allowing for installation without requiring certified plumbing or professional expertise.
